(19) United States
(12) Patent Application Publication
(10) Pub. No.: US 2011/0162702 A1
(43) Pub. Date: Jul. 7, 2011

(54) QUASI-PYRAMIDAL TEXTURED SURFACES USING PHASE-SEGREGATED MASKS

(75) Inventors: Roy A. Carruthers, Stormville, NY (US); Keith E. Fogel, Yorktown Heights, NY (US); Daniel A. Inns, Yorktown Heights, NY (US); Katherine L. Saenger, Yorktown Heights, NY (US)

(73) Assignee: INTERNATIONAL BUSINESS MACHINES CORPORATION, Armonk, NY (US)

(21) Appl. No.: 12/683,091

(22) Filed: Jan. 6, 2010

(51) Int. Cl. H01L 31/0236; H01L 21/302; H01L 21/3065; H01L 21/308; C23F 1/00; H01L 23/00

(52) U.S. Cl. 136/256; 438/689; 438/712; 216/13; 257/618; 257/E21.218; 257/E21.231; 257/E23.002

(57) ABSTRACT

A method of texturing a surface of a substrate utilizing a phase-segregated mask and etching is disclosed. The resulting textured surface, which can be used as a component of a solar cell includes, in one embodiment, a randomly mixed collection of flat-topped and angled surfaces providing local high points and local low points. The flat-topped surfaces have an areal density of at least 1%, and the high points are coincident with the flat-topped surfaces. Moreover, a preponderance of said low points are approximately situated in a single common plane parallel to the plane defined by the flat-topped surfaces.

### BACKGROUND

In one embodiment, the present invention relates to solar cell manufacturing, and more particularly to a method that utilizes a self-assembled phase-segregated mask in combination with etching to form quasi-pyramidal textured surfaces useful for solar cell applications.

Silicon solar cells typically have textured (i.e., specially roughened) front surfaces to increase the efficiency of light absorption. These textured surfaces decrease the fraction of incident light lost to reflection relative to the fraction of incident light transmitted into the cell since photons incident on the side of an angled feature will be reflected onto the sides of adjacent angled features and thus have another chance to be absorbed. Moreover, the textured surfaces increase internal absorption, since light incident on an angled silicon surface will typically be deflected to propagate through the silicon at an oblique angle, thereby increasing the length of the path taken to reach the silicon cell's back surface, as well as making it more likely that photons reflected from the silicon back surface will impinge on the front surface at angles compatible with total internal reflection and light trapping.

At present, there are many approaches for texturing silicon. One such prior art approach for texturing a silicon surface is described, for example, in D. Macdonald et al., “Texturing Industrial Multicrystalline Silicon Solar Cells,” in ISES 2001 World Solar Congress. In this publication, it is shown that single crystal (001) silicon can be textured in KOH based solutions to form densely-packed random arrays of square-based (111)-faced pyramidal facets several microns high. This type of texturing is nearly ideal for silicon solar cells, but it is restricted to cases in which the silicon is single crystal and thick enough to tolerate a texturing process that thins the silicon by perhaps 5 to 20 microns (i.e., 2 to 3 times the final peak-to-valley roughness). While this silicon loss may be eliminated with the use of lithographically-defined masks in conjunction with KOH and/or other anisotropic etches, this prior art method is unsuitable for silicon that is not single crystal.

Some distinctive texturing in silicon has been achieved with a combination of reactive ion etching (RIE) and a mask comprising closely packed self-assembled polymer spheres as disclosed, for example, in H. L. Chen et al. entitled “Using colloidal lithography to fabricate and optimize sub-wavelength pyramidal and honeycomb structures in solar cells,” Optics Express 15 14793 (2007). This prior art approach has the advantages of (i) not producing additional silicon thinning, and (ii) not requiring optical lithography or single crystal silicon. However, it is not yet clear whether this prior art approach will be scalable to large areas with acceptable uniformity and cost, and if the feature shapes (typically densely-packed mesas with steeply sloped, near-vertical sidewalls) are as easy to integrate and as optimal optically as the more conventional (111)-faced pyramidal facets.

Given the uncertainties with the existing prior art RIE/polymer sphere method mentioned above, it would be desirable to have an alternative method providing all of the advantages of the RIE/polymer sphere method (no lithography, minimal silicon thinning, suitable for silicon that is not single crystal), but with feature shapes having less steeply shaped sidewalls.

### SUMMARY OF THE INVENTION

A texturing method which avoids the drawbacks with prior art methods is disclosed that employs a combination of etching and a self-assembled phase-segregated mask to form a quasi-pyramidal textured surface. The term “phase-segregated mask” denotes a mask fabricated from a phase-segregating material composed of two or more elements that can be separated into distinct components of a characteristic feature size upon subjecting the phase-segregating material to phase segregation. The term “self-assembled” indicates that the phase segregation process by which the two or more elements in the phase-segregating material segregate into distinct components occurs as a consequence of specific, local interactions among the components themselves, without external direction. The term “quasi-pyramidal textured surface” is used throughout the present disclosure to denote a surface including some approximation of at least some of the features of an ideal pyramidal textured surface, wherein an ideal pyramidal-textured surface comprises a collection of closely-packed pyramidal protrusions, where each protrusion has angled side faces and a cross section that is triangular with a pointy top in at least two orthogonal dimensions. Deviations from the ideal pyramidal texture may occur in several ways. For example, the protrusions might be conical rather than pyramidal, the protrusion sidewalls viewed in cross section might be arc-shaped rather than straight, the protrusions might be ridges rather than isolated pyramids (e.g., a triangular cross section in only one of two orthogonal dimensions), and/or there may be flat-topped regions between or on top of some protrusions.

In one embodiment, the quasi-pyramidal textured surface includes a randomly mixed collection of flat-topped and angled surfaces providing local high points and local low points, wherein said flat-topped surfaces have an areal density of at least 1%, said high points are coincident with the flat-topped surfaces, and wherein a preponderance of said low points are approximately situated in a single common plane parallel to the plane defined by the flat-topped surfaces. In another embodiment, the textured surface includes few or no flat-topped surfaces.

In one aspect of the invention, a method of texturing a surface is provided. The method includes forming a layer of a phase segregating material atop a substrate. The substrate may optional include a barrier layer located thereon. The layer of phase segregating material is phase segregated to produce a phase-segregated material comprising a mix of first phase components and second phase components, wherein each phase component has a characteristic feature size. A phase-segregated etch mask is formed by selectively removing at least one set of components of the phase-segregated material while leaving at least one other set of components of the phase-segregated material. Exposed surfaces of the optional underlying barrier layer and/or the underlying substrate layer are etched to form a textured substrate having high regions, low regions, and angled surfaces between them. After texturing the substrate, the remaining one set of components can be removed by etching.

In another aspect of the invention, a structure including a layer of material having a textured surface is provided. Specifically, a structure is provided in which the textured surface includes a randomly mixed collection of flat-topped and angled surfaces providing local high points and local low points. The flat-topped surfaces have an areal density of at least 1%, and the high points are coincident with the flat-topped surfaces. Moreover, a preponderance of the low points are approximately situated in a single common plane parallel to the plane defined by the flat-topped surfaces. In one embodiment, the layer of material having the texture surface can be a component of a solar cell. In another embodiment, the layer of material having a textured surface can be a component of a semiconductor device structure. In yet another embodiment, the layer of material having the textured surface can be a component of any other type of structure, including, for example, a decorative structure, that requires texturing of at least one layer thereof.

### BRIEF DESCRIPTION OF SEVERAL VIEWS OF THE DRAWINGS

FIG. 1 is a pictorial representation (through a cross sectional view) depicting an initial structure including a substrate to be textured and an optional barrier layer that can be employed in one embodiment of the present invention.

FIG. 2 is a pictorial representation (through a cross sectional view) depicting the initial structure of FIG. 1 after forming a layer of phase segregating material on an upper surface of the initial structure.

FIG. 3A is pictorial representation (through a cross sectional view) depicting the structure of FIG. 2 after phase segregating the layer of phase segregating material to produce a phase-segregated material having at least two distinct components, wherein each component has a characteristic feature size and shape, while. FIGS. 3B-3C show examples (through a plan view) of two characteristic shapes consistent with the cross section of FIG. 3A.

FIG. 4 is a pictorial representation (through a cross sectional view) depicting the structure of FIG. 3A after forming a phase-segregated etch mask by selectively removing at least one set of components of the phase-segregated material while leaving at least one other set of components of the phase-segregated material, and etching the exposed optional barrier layer.

FIG. 5 is a pictorial representation (through a cross sectional view) depicting the structure of FIG. 4 after texturing the exposed substrate.

FIG. 6 is a pictorial representation (through a cross sectional view) depicting the structure of FIG. 5 after removing the phase-segregated etch mask and some or all of the remaining barrier layer.

FIGS. 7A-7B are cross sectional and tilted, respectively, SEM images of Si texture produced in accordance with an embodiment of the present invention using an Al—Si phase-segregating material, a phase-segregating anneal of 450° C./2 min, and a 15-minute reactive ion etch.

FIGS. 8A-8B are cross sectional and tilted, respectively, SEM images of Si texture produced in accordance with an embodiment of the present invention using an Al—Si phase-segregating material, a phase-segregating anneal of 450° C./2 hour, and a 12-minute reactive ion etch.

FIGS. 9A-9B are cross sectional and titled, respectively, SEM images of Si texture produced in accordance with an embodiment of the present invention using an Al—Si phase-segregating material, a phase-segregating anneal of 450° C./2 hour, and a 20-min reactive ion etch.

### DETAILED DESCRIPTION

The present invention, which provides a method of texturing a substrate utilizing a self-assembled phase-segregated mask in combination with etching to form a quasi-pyramidal textured surface which, in one embodiment, is useful for solar cell applications, will now be described in greater detail by referring to the following discussion and drawings that accompany the present application. It is observed that the drawings of the present application are provided for illustrative proposes and, as such, the drawings are not drawn to scale.

In the following description, numerous specific details are set forth, such as particular structures, components, materials, dimensions, processing steps and techniques, in order to provide an understanding of some aspects of the present invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

As mentioned above, the instant disclosure provides a texturing method that employs a self-assembled phase-segregated mask in combination with etching to form a quasi-pyramidal textured surface. In one embodiment, the textured surface includes a randomly mixed collection of flat-topped and angled surfaces providing local high points and local low points, wherein said flat-topped surfaces have an areal density of at least 1%, said high points are coincident with the flat-topped surfaces, and wherein a preponderance of said low points are approximately situated in a single common plane parallel to the plane defined by the flat-topped surfaces. In another embodiment, the textured surface contains few or no flat-topped surfaces.

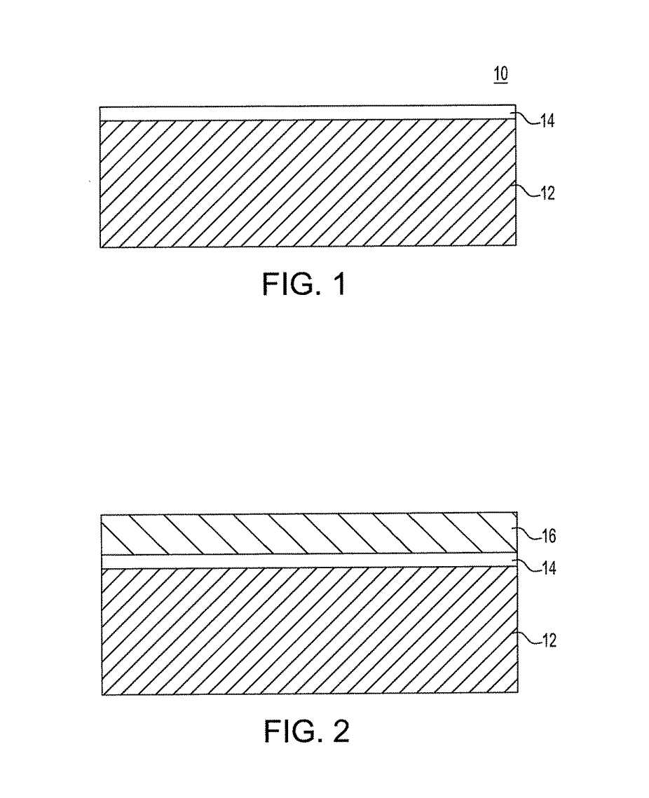

The basic processing steps of the method that can be used in the invention to provide the quasi-pyramidal textured surface will now be described in greater detail by referring to FIGS. 1-6.

Reference is first made to FIG. 1 which illustrates an initial structure 10 that can be employed in one embodiment of the present invention. The initial structure 10 includes a substrate (or a layer) 12 to be textured and an optional barrier layer 14 that is located on an upper surface of substrate 12.

The initial structure 10 illustrated in FIG. 1 is comprised of materials that are well known to those skilled in the art, and the initial structure 10 can be formed utilizing techniques that are also well known in the art.

In one embodiment, the substrate 12, which is to be subsequently textured by the method of the present invention, can be comprised of a semiconductor material including, but not limited to Si, SiGe, SiGeC, SiC, Ge alloys, GaAs, InAs, InP and other III/V or II/Vi compound semiconductors. In addition to these listed types of semiconductor materials, the substrate 12 can also be a layered semiconductor such as, for example, Si/SiGe, Si/SiC, silicon-on-insulators (SOIs) or silicon germanium-on-insulators (SGOIs). In some embodiments of the invention, the substrate 12 is a Si-containing semiconductor material, i.e., a semiconductor material that includes silicon. The semiconductor material that can be employed as substrate 12 can be single crystalline, polycrystalline, multicrystalline, and/or hydrogenated-amorphous. The semiconductor materials that can be employed as substrate 12 can be undoped, doped or contain doped and undoped regions therein.

In addition to semiconductor materials, the substrate 12 may also comprise or include a dielectric material such as, for example, glass (e.g., silica typically with one or more additives from the group including Al, B, C, K, Na, and P), SiO₂, SiN, plastic, or diamond-like carbon. In yet another embodiment, the substrate 12 may comprise or include a metal, or a transparent conductor including, for example, a metal oxide or conductive forms of carbon. In further embodiments of the invention, the substrate 12 may include any combination, including multilayered stacks of the above mentioned semiconductor materials, dielectric materials and transparent conductors.

For solar cell applications, substrate 12 to be textured would preferably comprise either (i) at least one semiconductor layer or (ii) a transparent layer or substrate on which at least one semiconductor layer would be subsequently formed after the transparent layer is textured.

The optional barrier layer 14 that can be formed on an upper surface of substrate 12 would typically comprise an oxide, a nitride, an oxynitride or any combination including multilayers thereof. When the substrate 12 is a semiconductor material, the optional barrier layer 14 can be a semiconductor oxide, a semiconductor nitride and/or a semiconductor oxynitride. In one embodiment of the invention, the optional barrier layer 14 is composed of silicon oxide. The optional barrier layer 14 can be formed utilizing a conventional deposition process such as, for example, chemical vapor deposition (CVD), plasma enhanced chemical vapor deposition (PECVD), atomic layer deposition (ALD), physical vapor deposition (PVD), and chemical solution deposition. Alternatively, the optional barrier layer 14 can be formed by a thermal growth process including, but not limited to oxidation and/or nitridation.

When present, the optional barrier layer 14 has thickness that is typically less than 300 nm. When functioning as a barrier layer, barrier layer 14 should be thick enough to prevent undesired intermixing between substrate 12 and species within the phase-segregating material (for example, during thermal treatments that might be required to induce phase segregation), yet thin enough to easily be removed selectively with respect to the portion of the phase-segregated material remaining behind as a mask. A preferred thickness for such a barrier layer might be in the range from 10 nm to 30 nm. When a hard mask function is desired for the barrier layer (for example, when the phase-segregated mask has a poor etch selectivity to the substrate and the barrier layer material has a good etch selectivity to the substrate), thicker barrier layers might be preferred. In this scenario, the phase-segregated mask could be used as a mask to pattern the barrier layer, and the barrier layer could be used as a mask for patterning the substrate layer. The optimum thickness of a barrier layer used as a hard mask would thus be determined by the barrier-to-substrate etch selectivity and the anticipated amount of substrate etching desired, and might be, for example, in the range from 100 nm to 300 nm.

Referring now to FIG. 2, there is shown the structure after forming a layer of phase segregating material 16 on an upper surface of the optional barrier layer 14, if present, or on an upper surface of substrate 12, if the optional barrier layer 14 is not present.

The layer of phase segregating material 16 is composed of any material that includes two or more elements that are above their solubility limit such that a stable compound or complex of the two or more elements cannot form. Additionally, the layer of phase segregating material 16 is any material that can phase segregate, e.g., separate, into two or more distinct components during a subsequent phase segregation step. Each of the components that forms after phase segregation has a characteristic feature size and shape. In one embodiment of the invention, the layer of phase segregating material 16 is composed of an Al—Si alloy. In another embodiment, some or all of the Si can be replaced by germanium. When Al—Si alloys are employed, the Si:Al ratio (by atomic percent) that can be employed is within a range from 95:5 to 5:95, with a ratio of Si:Al from 75:25 to 25:75 being more typical. It is noted that the ratio ranges mentioned above, while being specific to Si and Al, are also applicable for other systems as well.

The layer of phase segregating material 16 can be formed utilizing known deposition processes such as co-evaporation from separated Al and Si sources; co-sputtering from individual Al and Si targets; and rf and/or dc-magnetron sputtering from an Al—Si alloy target. Co-evaporation and co-sputtering methods may be implemented so as to provide compositionally homogeneous alloys or, alternatively and less preferably, alloy layers comprising alternating Al-rich and Si-rich layers with the desired average composition.

The preferred thickness of the layer of phase segregating material 16 that is formed will depend on the type of phase segregating material employed as well as the etch selectivity of the resulting phase segregated mask with respect to the substrate and/or barrier layer materials being etched. Layers that are too thin will not provide sufficient masking; layers that are too thick may yield segregated phases lacking the desired morphology (e.g., approximately columnar in cross-section view) after phase segregation. Typically, the layer of phase segregating material 16 has a thickness from 50 nm to 500 nm, with a thickness from 100 nm to 300 nm being more typical.

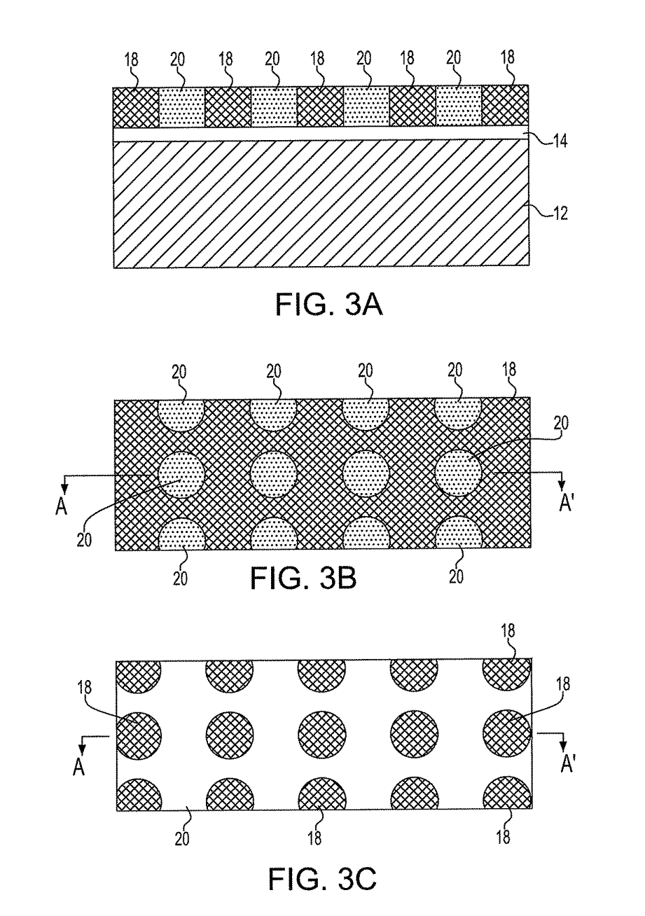

Referring now to FIG. 3A, there is illustrated the structure of FIG. 2 after performing phase segregation which separates the two or more elements of the layer of phase segregating material 16 into a phase-segregated material having two or more distinct components, each having a characteristic feature size and shape. Specifically, FIG. 3A illustrates an embodiment in which two elements, e.g., Al and Si, are present within the layer of phase segregating material 16, which upon phase segregation separates into a phase-segregated material including a plurality of first segregated components 18 and a plurality of second segregated components 20. Collectively the segregated components 18 and 20 form a phase-segregated material.

As mentioned above, the columnar morphology shown in FIG. 3A is preferred for the separated phase components. Examples of two possible idealized geometries for phase-segregated components 18 and 20 are shown in FIGS. 3B-3C (in plan view); the phase-segregated material of FIG. 3B has round pillars of component 20 and a composition in which component 18 predominates, whereas the phase-segregated material of FIG. 3C has round pillars of component 18 and a composition in which component 20 predominates. In one embodiment, the segregated components 18 are composed of Si, while segregated components 20 are composed of Al. Although two segregated components are described and illustrated, the present invention is not limited to forming only two segregated components. It is noted that the different segregated components that form have different etch rates associated therewith.

As mentioned above, each segregated component that is formed has a characteristic feature size and shape. The characteristic feature size of each of the segregated components is dependent on the elements being segregated, the thickness of the layer of phase segregating material, the deposition method and conditions used to deposit the phase segregating material, and the conditions used for phase segregation. Typically, the characteristic feature size of each element is from 0.2 microns to 2 microns, with a characteristic feature size from 0.5 microns to 1 microns being more typical. The features that are formed tend to be finer grained for a phase segregating material having a thickness of 50 nm or less, and coarser grained for a phase segregating material having a thickness of 200 nm or greater.

Phase segregation is performed by heating, i.e., annealing, the layer of phase segregating material 16. The anneal can be performed at a temperature from 300° C. to 600° C., with a temperature from 430° C. to 480° C. being more typical. The anneal can be performed in an inert ambient. By “inert ambient” it is meant an environment, typically gas or vapor, that does not form a reaction product with the various elements within the layer of phase segregating material 16. Typical examples of inert ambients that can be employed include Ar, He, Ne, Xe, N₂ and mixtures thereof, and these ambients in combination with H₂. In one embodiment, N₂ alone, or admixed, with Ar or He can be employed as the inert ambient. The anneal can be a furnace anneal, a rapid thermal anneal, a spike anneal or a laser anneal. The duration of the anneal, i.e., annealing time, may vary depending on the type of anneal employed as well as the type of phase segregating material employed. Typically, the anneal is performed for a duration from 0.5 hours to 4 hours, with anneal duration of 2 hours being more typical.

For co-evaporated Al—Si alloys deposited at room temperature, deviations from the round pillar shapes of FIGS. 3B-3C can be substantial. In such an embodiment, the phase-segregated pattern may comprise an irregular collection of meandering line shapes rather than a regular array of dots. If desired, the features of the remaining component may be trimmed (made smaller in lateral dimension) by additional etching, providing that the amount etched is small enough to leave a sufficient thickness of the mask.

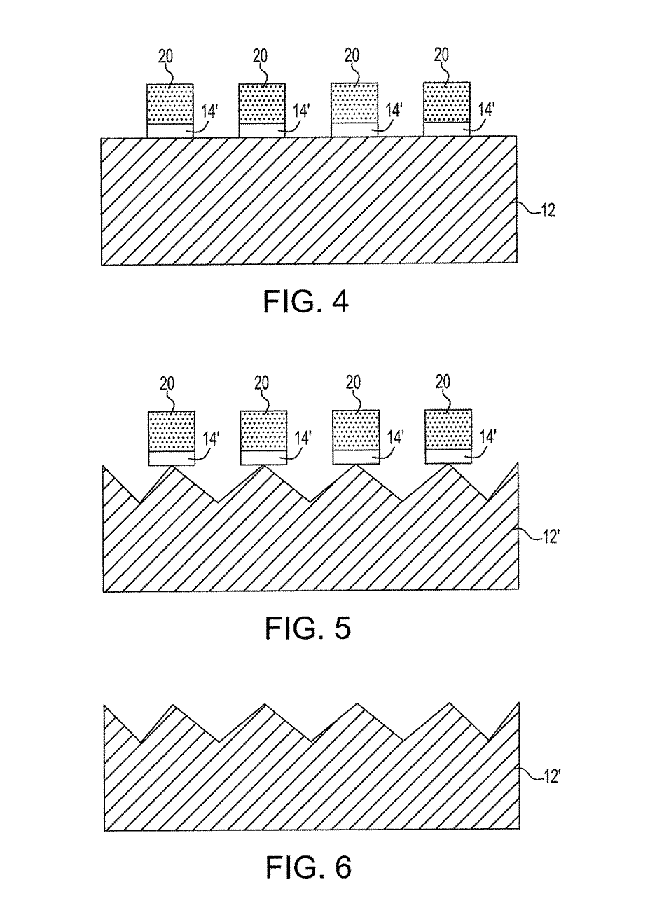

Referring now to FIG. 4, there is shown the structure of FIG. 3A after selectively removing one set of segregated components from the structure to form a phase-segregated etch mask. The structure of FIG. 4 also shows the removal of the underlying portions of the optional barrier layer 14 that are not protected by the remaining set of segregated components. For illustrative purposes only, FIG. 4 shows the structure in which the set of segregated components 18 is selectively removed using the set of segregated component 20 as an etch mask. In FIG. 4, reference numeral 14′ is used to denote the remaining portions of the optional barrier layer 14 that are located beneath the remaining set of segregated components 20.

The removal of one set of the segregated components from the structure is performed utilizing any etching process that can selectively remove a desired set of segregated components from the structure. In one embodiment, the etch can include a dry etch process such as, for example, reactive ion etching or plasma etching. In another embodiment, a chemical wet etch process can be used. In still yet another embodiment of the invention, a combination of dry etching and wet etching can be employed.

The etch chemistry used at this point of the process will be dependent upon the material of the segregated component being selectively removed. The choice of etch chemistry employed is within the knowledge of one skilled in the art. For example, when Si is present in the set of segregated components being removed and Al is present in the set of segregated components not being removed, the etch includes the use of chemicals that selectively remove Si as compared to Al. In such an embodiment, reactive ion etching utilizing a mixture of oxygen and a fluorine-containing gas (e.g., carbon tetrafluoride, CF₄) can be used to remove the set of Si-containing segregated components from the structure, while using the set of segregated Al components as an etch mask. During the selective removal of the Si-containing segregated components from the structure, the etch used to selectively remove the Si-containing segregated components can also remove the portions of the optional barrier layer 14 that are exposed after removing the Si-containing segregated components. This is particularly easy to do when the barrier layer is composed of SiO₂. In other embodiments of the present invention, a separate etch can be used to remove the underlying portions of the optional barrier layer after the Si-containing segregated components are removed from the structure.

In embodiments in which Al is present in the set of segregated components being removed and Si is present in the set of segregated components not being removed, the etch includes the use of chemicals that selectively remove Al as compared to Si. In such an embodiment, a wet etch utilizing hot phosphoric acid can be used to remove the Al-containing segregated components from the structure, while using the segregated Si components as an etch mask. During the selective removal of the Al-containing segregated components from the structure, the etch used to selectively remove the Al-containing segregated components can also remove the portions of the optional barrier layer 14 that are exposed after removing the Al-containing segregated components. However, in the case of a barrier layer composed of SiO₂, a separate etch is preferably used to remove the underlying portions of the optional barrier layer after the Al-containing segregated components are removed from the structure. Examples of an etch to remove such an SiO₂ barrier layer include reactive ion etching in a fluorine-containing gas, or an etch in aqueous HF that is short enough not to remove the Al.

Referring now to FIG. 5, there is illustrated the structure of FIG. 4 after etching the now exposed portions of the substrate 12 that are not protected by the remaining set of segregated components of the phase-segregated mask forming a textured substrate 12′. The etch used in this step of the invention is an etch that selectively removes the exposed portions of the substrate 12 relative to the remaining set of segregated components of the phase-segregated mask. The etch can include one of the etching techniques mentioned above, i.e., one of dry etching and wet etching. In one embodiment, a dry etching process, such as RIE, is employed in forming the structure shown in FIG. 5. The optimum RIE conditions for texturing the substrate will be moderately anisotropic, by which it is meant not entirely anisotropic (which would give vertical sidewalls) and not entirely isotropic (which would give very rounded sidewalls with the possibility of completely undercutting the mask before the desired depth of texturing is achieved). In another embodiment, a crystallographic etching process can be used to form the structure shown in FIG. 5.

Referring now to FIG. 6, there is illustrated the structure of FIG. 5 after removing the remaining set of segregated components, and the optional remaining barrier layer 14′ from the structure providing a substrate 12′ that is textured. The removal of the remaining set of segregated components of the phase-segregated mask can be achieved utilizing one of the etching processes mentioned above. That is, one of dry etching and wet etching can be employed. In one embodiment and when the remaining set of segregated components is composed of Al, hydrophosphoric acid (HPA) and/or dilute hydrofluoric acid (dHF) can be employed.

It is observed that the method described above and as illustrated within FIGS. 1-6 provides a textured substrate 12′ that has a textured surface. In one embodiment of the invention, the textured surface includes a randomly mixed collection of flat-topped and angled surfaces providing local high points and local low points. The flat-topped surfaces have an areal density of at least 1%, and the high points are coincident with the flat-topped surfaces. A preponderance, i.e., substantially number, of the low points of the textured surface are approximately situated in a single common plane parallel to the plane defined by the flat-topped surfaces. This aspect of the invention can be better seen in the SEM images containing within the following examples. In some embodiments, the method can produce a textured substrate having few or no flat-topped surfaces.

The following examples are provided to illustrate some aspects of the present application. The details within the following examples are not limiting and represent various embodiments of the invention.

### EXAMPLES

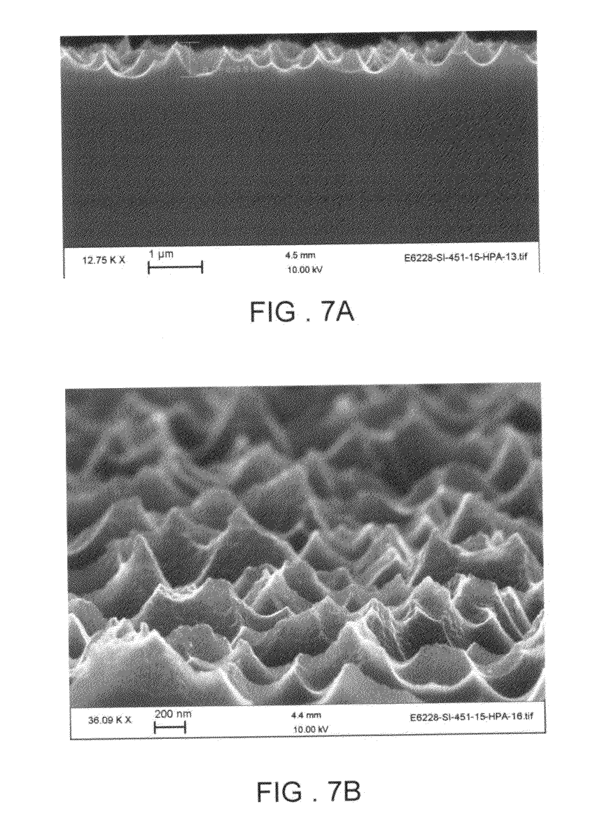

FIGS. 7A-9B show SEM images in cross section (7A, 8A and 9A) and tilted (7B, 8B and 9B) views for three exemplary Si textures produced by the process described above and as illustrated within FIGS. 1-6 for the case of a 200 nm thick Al—Si alloy layer (Si/Al ratio of approximately 1.3) deposited on room temperature (20° C.-30° C.) substrates by electron-beam coevaporation of Al and Si, a post-deposition phase segregation anneal at 450° C., and RIE conditions of 10% oxygen in CF₄ (45/5 sccm), 300 W (approximately 0.65 W/cm²) to the (bottom) electrode on which the sample sits, and a gas pressure of 100 mTorr. Following RIE, the Al mask was removed either with hot phosphoric acid, followed by dilute hydrofluoric acid (dHF), or by dHF alone.

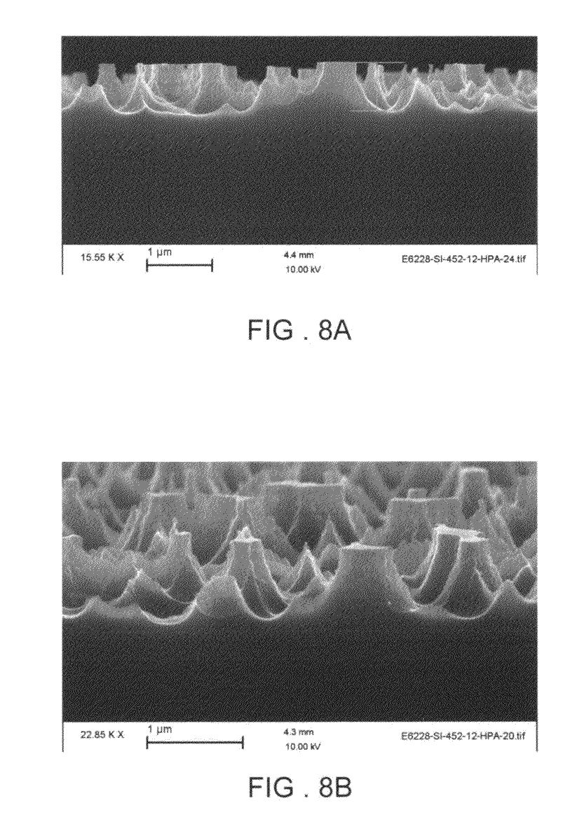

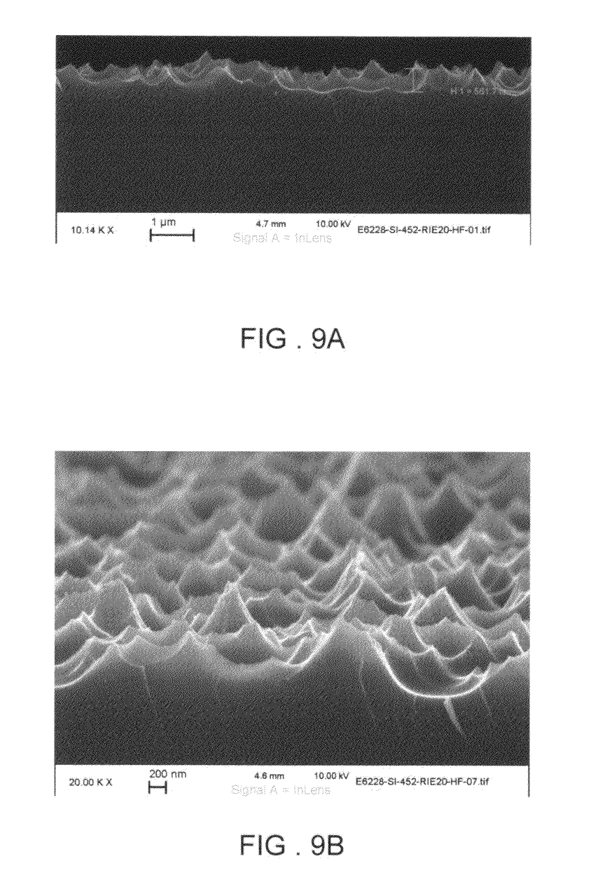

The sample shown in FIGS. 7A-7B was annealed at 450° C. for 2 minutes and RIE'd for 15 minutes. The sample shown in FIGS. 8A-8B was annealed at 450° C. for 2 hours and RIE'd for 12 minutes, while the sample shown in FIGS. 9A-9B was annealed at 450° C. for 2 hours and RIE'd for 20 minutes. It is noted that the flat-topped mesa texture of FIGS. 8A-8B is not optimal for use in solar cell applications since the mesa tops might contribute to specular reflection. Fortunately, there is a wide process window of mask geometries and RIE conditions that can provide textures similar to those FIGS. 7A, 7B, 9A and 9B. The textures of FIGS. 7A, 7B, 9A and 9B includes a randomly mixed collection of flat-topped and angled surfaces providing local high points and local low points. The flat-topped surfaces have an areal density of at least 1%, and the high points are coincident with the flat-topped surfaces. A preponderance, i.e., a substantial number, of the low points of the textured surface is approximately situated in a single common plane parallel to the plane defined by the flat-topped surfaces. As such, such textures samples are suitable for use in solar cell applications.

While the present invention has been particularly shown and described with respect to preferred embodiments thereof, it will be understood by those skilled in the art that the foregoing and other changes in forms and details may be made without departing from the spirit and scope of the present invention. In particular, it should be understood that structures including a layer of material having a textured surface provided by the method of this invention are not limited to solar cells and other semiconductor device structures, but may include, for example, structures whose purpose is primarily decorative. It is therefore intended that the present invention not be limited to the exact forms and details described and illustrated, but fall within the scope of the appended claims.

What is claimed is:

1. A method of texturing a surface comprising:
forming a layer of a phase segregating material atop a substrate;
phase segregating the layer of phase segregating material to produce a phase-segregated material comprising a mix of first phase components and second phase components, each phase component having a characteristic feature size;
forming a phase-segregated etch mask by selectively removing at least one set of components of the phase-segregated material, while leaving at least one other set of components of the phase-segregated material; and
etching at least exposed surfaces of the substrate to form a textured substrate having high regions, low regions and angled surfaces between them.

2. The method of claim 1 wherein said substrate includes a barrier layer, and said layer of phase segregating material is formed on an upper surface of the barrier layer.

3. The method of claim 2 wherein said etching also removes exposed portions of the barrier layer, while maintaining a portion of said barrier layer under said phase-segregated etch mask.

4. The method of claim 3 further comprising removing the phase-segregated etch mask and the portion of said barrier layer under said phase-segregated etch mask after etching.

5. The method of claim 1 further comprising removing said phase-segregated etch mask after etching.

6. The method of claim 1 wherein said substrate is selected from a semiconductor material, a dielectric material, a metal, a transparent conductor and any combination including multilayered stacks thereof.

7. The method of claim 1 wherein said substrate is silicon or glass.

8. The method of claim 1 wherein said forming the layer of phase segregating material includes selecting from at least one of Al—Si, Al—Ge, and Al—Si/Al—Ge mixtures.

9. The method of claim 8 wherein said layer of phase segregating material includes an Al—Si alloy, said Al—Si alloy having a Si/Al ratio (by atomic percent) from 95:5 to 5:95.

10. The method of claim 1 wherein said forming the layer of phase segregating material includes co-evaporation from separate sources, sputtering from an alloy target, and co-sputtering from separate sources.

11. The method of claim 1 wherein said phase segregating includes annealing at a temperature within a range from 400° C. to 550° C.

12. The method of claim 1 wherein said etching includes reactive ion etching.

13. The method of claim 12 wherein said reactive ion etching includes a mixture of oxygen and a fluorine-containing gas.

14. The method of claim 1 wherein said textured substrate has a textured surface including a randomly mixed collection of flat-topped and angled surfaces providing local high points and local low points, wherein said flat-topped surfaces have an areal density of at least 1%, said high points are coincident with the flat-topped surfaces, and wherein a preponderance of said low points are approximately situated in a single common plane parallel to the plane defined by the flat-topped surfaces.

15. A structure including a layer of material having a textured surface, said textured surface comprising a randomly mixed collection of flat-topped and angled surfaces providing local high points and local low points, wherein said flat-topped surfaces have an areal density of at least 1%, said high points are coincident with the flat-topped surfaces, and wherein a preponderance of said low points are approximately situated in a single common plane parallel to the plane defined by the flat-topped surfaces.

16. The structure of claim 15 wherein said textured surface is selected from a semiconductor material, a dielectric material, a transparent conductor and any combination including multilayered stack thereof.

17. The structure of claim 16 wherein said textured surface is silicon or glass.

18. The structure of claim 15 wherein said layer of a material having a textured surface is a component of a solar cell.

19. The structure of claim 15 wherein said layer of a material having a textured surface is a component of a semiconductor device structure.

20. A structure including a layer of material having a textured surface, said textured surface comprising a randomly mixed collection of upper and angled surfaces providing local high points and local low points, wherein said high points are coincident with the upper surfaces, and wherein a preponderance of said low points are approximately situated in a single common plane parallel to the plane defined by the upper surfaces.

21. The structure of claim 20 wherein said textured surface is selected from a semiconductor material, a dielectric material, a metal, a transparent conductor and any combination including multilayered stack thereof.

22. The structure of claim 20 wherein said textured surface is silicon or glass.

23. The structure of claim 20 wherein said layer of a material having a textured surface is a component of a solar cell.

24. The structure of claim 20 wherein said layer of a material having a textured surface is a component of a semiconductor device structure.
